(19) United States
(12) Patent Application Publication
(10) Pub. No.: US 2015/0047694 A1
(43) Pub. Date: Feb. 19, 2015

(54) USE OF A MULTILAYER STRUCTURE BASED ON A HALOGENATED POLYMER AS A PROTECTIVE SHEET OF A PHOTOVOLTAIC MODULE

(71) Applicants: ARKEMA FRANCE, Colombes (FR); COMMISSARIAT A L'ENERGIE ATOMIQUE ET AUX ENERGIES AL TERNATIVES, Paris (FR)

(72) Inventors: Anthony Bonnet, Saint Laurent De Mure (FR); Stephane Cros, Chambery (FR); Manuel Hidalgo, Brignais (FR)

(73) Assignees: ARKEMA FRANCE, Colombes (FR); COMMISSARIAT A L'ENERGIE ATOMIQUE ET AUX ENERGIES AL TERNATIVES, Paris (FR)

(21) Appl. No.: 14/386,056

(22) PCT Filed: Mar. 22, 2013
(86) PCT No.: PCT/FR2013/050618

§ 371 Date: Sep. 18, 2014

(30) Foreign Application Priority Data
Mar. 23, 2012 (FR) 1252615

(51) Int. Cl. H01L 31/049; H01L 31/048

(52) U.S. Cl. CPC H01L 31/049; H01L 31/0481
USPC 136/251

(57) ABSTRACT

The present invention relates to the use of a specific multilayer structure in the front and/or rear protective sheet of a photovoltaic module comprising photovoltaic cells covered with an encapsulant. This multilayer structure comprises a substrate enclosing at least one halogenated polymer and at least one stack of one layer (A) of SiO2 and one layer (B) of an SiOxNyHz material disposed between the substrate and the layer (A), said layers having given thicknesses. This stack is disposed on the face of the substrate turned towards the encapsulant and optionally on the opposing face of the substrate. It also relates to a photovoltaic module comprising the abovementioned multilayer structure in the front and/or rear protective sheet thereof.

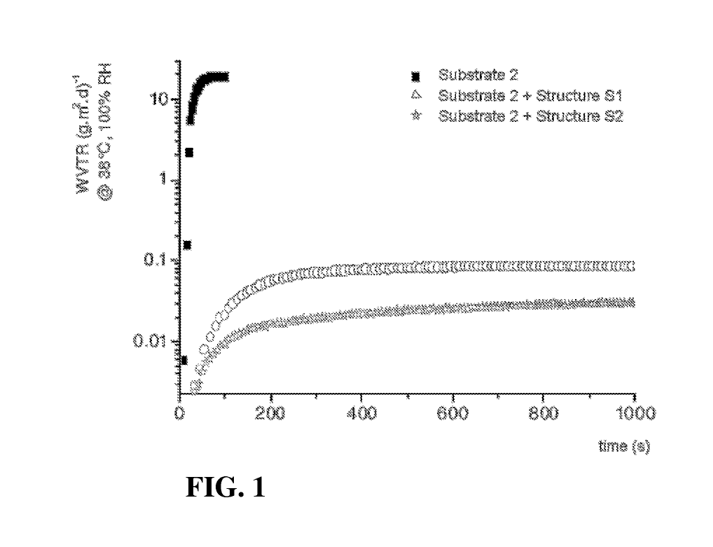

### TECHNICAL FIELD

The present invention relates to the use of a multilayer structure in the protective frontsheet and/or backsheet of a photovoltaic module, said multilayer structure comprising a substrate based on halogenated polymer covered with at least one stack of two layers of SiO₂ and SiOₓN_{y}H_{z} respectively. It also relates to a photovoltaic module comprising the abovementioned multilayer structure in its protective frontsheet and/or backsheet.

### BACKGROUND OF THE INVENTION

Global warming, related to the greenhouse gases given off by fossil fuels has led to the development of alternative energy solutions which do not emit such gases during operation thereof, such as, for example, photovoltaic modules. The latter can be used effectively to produce electricity connected to the electric circuit, either in a solar park or solar power plant, or from numerous small specific producers, to supply electricity to a dwelling or to provide electricity to devices which may not be connected, from time to time or permanently, to the electric circuit, such as cell phones, ticket machines, bus shelters, appliances or devices for lighting in isolated spots, and the like.

A photovoltaic module, or solar panel, is an electrical generator which makes it possible to convert a portion of the solar energy which it receives into a direct current; it is composed of an assembly of photovoltaic cells based on a semiconductor material, such as silicon, which cells are connected to one another electrically and are protected by an adhesive encapsulating material, generally based on ethylene/vinyl acetate (EVA) copolymer. An upper protective sheet (or frontsheet) and a protective sheet at the back of the module (or backsheet) are positioned against each face of the encapsulant. These protective frontsheets and backsheets of the modules can in their turn be composed of one or more layers of identical or different materials. Depending on the technology of the photovoltaic cells to be protected and on the characteristics desired for the module, the frontsheets and backsheets should exhibit specific properties. Thus, for example, the panels currently most widely used comprise cells based on mono- or polycrystalline silicon, encapsulated by EVA and protected, as frontsheet, by a glass sheet and, as backsheet, by a multilayer structure comprising poly(ethylene terephthalate) (PET) between two layers based on a fluorinated polymer, such as poly(vinyl fluoride) (PVF) or poly(vinylidene fluoride) (PVDF). In this configuration, the glass frontsheet offers good protection from impacts, good transparency and excellent protection against moisture, despite the disadvantages of a sizable weight as the glass, with a thickness typically of 3 mm, is the main contributor to the weight of the module. The glass also offers good resistance to aging. In this configuration, the role of the backsheet is also to protect the cell against moisture, even if the level of protection is far below that offered by the glass, but also to ensure the electrical insulation of the cells, to block UV rays and to exhibit good mechanical strength, in particular to tearing, while allowing the module to withstand aging during its lifetime, which should in many cases exceed 20 years. It is understood that the nature and the design of these protective frontsheets and backsheets thus play an essential role in the longevity of the photovoltaic module.

In order to overcome the disadvantage of the lack of lightness, indeed even of flexibility, of the modules having a glass frontsheet, a person skilled in the art has thought of replacing it with polymer films which have to offer a maximum of satisfactory properties, in particular in terms of transparency, of resistance to aging and of impermeability to gases, in particular to oxygen and to water vapor. However, it is known that polymer films offer a protection to gases which is at best mediocre.

Provision has been made to improve the gastightness of a photovoltaic module by depositing, on its protective frontsheet made of polymer, a thin layer of a dense inorganic material. Thus, the document US 2010/0258162 discloses a flexible photovoltaic module front protective layer comprising a transparent substrate made of halogenated polymer, such as PVDF (polyvinylidene fluoride) optionally covered, on the external side, with an SiOₓ layer intended to reinforce its barrier properties. It is known that the SiOₓ layer can be deposited by processes such as chemical vapor deposition, reactive sputtering or thermoevaporation. However, this type of inorganic deposit generates mechanical stresses relating in particular to the differences in mechanical behavior and thermal behavior between the inorganic layer and the polymer, in particular to the differences in elastic moduli, in deformabilities and in thermal expansion coefficients. These stresses bring about damage to the inorganic layer deposited, which has the effect of limiting its functional properties. Cracks may then appear, which reduce the barrier properties to gases of the assembly formed by the polymer substrate and the inorganic deposit. Furthermore, these SiOₓ deposition techniques are relatively expensive. In order to overcome this disadvantage, it is admittedly possible to deposit the SiOₓ layer by the sol-gel route. However, the layer thus obtained is porous and thus cannot perform its role of barrier layer to gases.

The solution provided in the document US 2003/0203210 is not satisfactory either. A process is described which consists in producing alternating stacks of inorganic layers and polymer layers (such as an acrylic polymer), having a thickness of 1 μm to several μm, on a thick polymer substrate, in particular based on polyesters, such as PET. The alternation of inorganic and organic layers makes it possible to decorrelate the defects in each inorganic layer and thus to considerably improve the barrier properties to gases, so that the polymer subtrate thus covered has barrier properties to gases which are sufficient to protect devices highly sensitive to the atmosphere, such as organic light-emitting diodes (OLEDs) and a fortiori photovoltaic devices much less sensitive to moisture. However, such alternating structures have a high production cost as a result of the use of multiple deposition chambers and of vacuum deposition techniques, which renders them not very suitable for use in photovoltaic modules.

Moreover, the natural aging of the polymer supports commonly used, such as PET, constitutes a major disadvantage for transparent structures which get exposed for a long time, typically many years, to attack by the light, in particular its ultraviolet component. Even when they are treated in order to be rendered gastight, polymer supports, such as the PET, can decompose as a result of the exposure of the support to minimum but not insignificant amounts of oxygen and water, in conjunction with the attack of the ultraviolet rays. It is also the case with the structure provided in the thesis by A. Morlier, Propriétés barrières de structures hybrides—Application à l′encapsulation des cellules solaires [Barrier properties of hybrid structures—Application to the encapsulation of solar cells], University of Grenoble (2011). This structure is prepared by deposition of polyhydropolysilazane (PHPS) on a PET substrate, followed by conversion of the PHPS by VUV and UV irradiation in order to form at least one stack having a total thickness of 250 nm and comprising a layer of PHPS partially converted into hydrogenated silicon nitride, a partially converted interfacial layer of silicon oxynitride and a thin layer of rigid silica. Different stacks are produced, optionally separated from one another by a PVA layer. While this structure exhibits indisputable advantages with respect to the prior art, its gastightness requires being further improved.

In point of fact, it is apparent to the applicant company that the use of a halogenated polymer makes it possible to solve this problem.

It has admittedly been suggested, in the document WO 2011/062100, to coat a PVC (polyvinyl chloride) substrate with a barrier-forming layer made of SiOₓ, obtained from a polysilazane solution and composed of silicon oxide having regions of different densities. However, no application to the protection of photovoltaic modules was envisaged, since this document is targeted at providing a protective film for an electroluminescent element.

It was also suggested, in the documents JP2011-143327 and JP2011-173057, to apply one or more barrier-forming layers to a substrate, which can be made of PVC, by deposition of perhydropolysilazane on the substrate, followed either by two VUV irradiations under different atmospheres or by a treatment of the substrate (in particular with UV radiation), followed by VUV irradiation. However, the VUV irradiation is always carried out in the presence of a high content of oxygen and/or water, which does not make it possible to obtain a satisfactory barrier layer.

Furthermore, provision has been made, in the document US 2011/0315206, to cover the front protective layer of a photovoltaic module, consisting of glass, with a transparent abrasion-resistant film consisting, for example, of a hydrophobic fluorinated polymer which is either charged with inorganic particles or inorganic-grafted. A hard layer forming a barrier to moisture can be inserted between the glass substrate and the film. This layer can in particular be formed of silicon oxide obtained from perhydropolysilazane. It would be desirable to be able to have available a photovoltaic module front or rear protective layer which is more flexible and lighter than that provided in this document.

Other front or rear protective layers for photovoltaic modules, including a halogenated polymer, have been described in the documents WO 2011/103341, EP 1 054 456, U.S. Pat. No. 6,335,479, US 2012/048349 and US 2007/295387. However, none of these documents discloses a structure comprising a layer of SiOₓN_{y}H_{z} interposed between a fluorinated substrate and an SiO₂ layer, this SiOₓN_{y}H_{z} layer being thicker than the SiO₂ layer.

### ACCOUNT OF THE INVENTION

A subject matter of the present invention is the use of a multilayer structure in the protective frontsheet and/or backsheet of a photovoltaic module comprising photovoltaic cells covered with an encapsulant. The protective frontsheet and/or backsheet in which the multilayer structure is included does not comprise a glass layer with a thickness of 50 μm or more. This multilayer structure comprises: (a) a substrate including at least one halogenated polymer and (b) at least one stack of an SiO₂ layer (A) and of a layer (B) made of SiOₓN_{y}H_{z} positioned between the substrate and the layer (A). Said stack is positioned on the face of the substrate turned toward the encapsulant and optionally on the opposite face of the substrate. The layer (A) and the layer (B) exhibit thicknesses (t_{A}, t_{B}) such that the thickness (t_{A}) of the layer (A) is less than or equal to 60 nm, the thickness (t_{B}) of the layer (B) is greater than twice the thickness (t_{A}) of the layer (A) and the sum of the thicknesses of layer (A) and of the layer (B) is between 100 nm and 500 nm, and in which z is strictly less than the ratio (x+y)/5, advantageously z is strictly less than the ratio (x+y)/10.

Another subject matter of the present invention is a photovoltaic module including photovoltaic cells protected by an encapsulant, a protective frontsheet and a protective backsheet, in which the protective frontsheet and/or backsheet comprises a multilayer structure as defined above and does not comprise a glass layer with a thickness of 50 μm or more.

The multilayer structure used according to the invention constitutes a film having good chemical resistance and good resistance to aging, which can be transparent and which makes it possible to protect photovoltaic components with respect to oxygen for the greatest number of years, this being achieved at an acceptable production cost. In particular, the use of a liquid-phase deposition technique for the two-layer stack according to the invention makes it possible to obtain, in a simple way and at low cost, a level of gastightness which cannot be obtained by conventional deposition technologies, such as physical vapor deposition and chemical vapor deposition.

### DETAILED DESCRIPTION OF EMBODIMENTS

The multilayer structure used according to the invention comprises and is preferably composed of a substrate including at least one halogenated polymer and at least one stack composed of a SiO₂ layer and of a layer made of material of SiOₓN_{y}H_{z} type interposed between the substrate and the SiO₂ layer. The layer of SiOₓN_{y}H_{z} type forms a layer of mechanical accommodation between the substrate and the SiO₂ layer and makes it possible to adjust the stresses between the substrate and the SiO₂ layer, which limits the deterioration of the SiO₂ layer and thus improves the gastightness of the SiO₂ layer. In other words, the interposition of a layer forming a mechanical interface which is thicker and less rigid than the SiO₂ layer makes it possible to prevent the SiO₂ layer from breaking.

In this structure, the substrate comprises at least one halogenated polymer which is preferably transparent. It is generally a thermoplastic polymer. The term “halogenated polymer” is understood to mean, within the meaning of the invention, a homopolymer or copolymer, at least one of the monomers of which comprises a C—X bond, where X is a fluorine, chlorine or bromine atom. The halogenated polymer can in particular be a fluorinated and/or chlorinated homo- or copolymer, preferably a fluorinated homo- or copolymer. The fluorinated homo- and copolymers can, for example, be chosen from those comprising at least 50 mol % and advantageously composed of monomers of formula (I):

CFX═CHX′ (I)
where X and X′ independently denote a hydrogen or halogen (in particular fluorine or chlorine) atom or a perhalogenated (in particular perfluorinated) alkyl radical, such as:
poly(vinylidene fluoride) (PVDF), preferably in the α form,
copolymers of vinylidene fluoride with, for example, hexafluoropropylene (HFP), chlorotrifluoroethylene (CTFE), hexafluoropropylene (HFP), trifluoroethylene (VF3) or tetrafluoroethylene (TFE),
trifluoroethylene (VF3) homo- and copolymers,
fluoroethylene/propylene (FEP) copolymers,
copolymers of ethylene with fluoroethylene/propylene (FEP), tetrafluoroethylene (TFE), perfluoromethyl vinyl ether (PMVE), chlorotrifluoroethylene (CTFE) or hexafluoropropylene (HFP), and
their blends,
   some of these polymers being in particular sold by Arkema under the Kynar® trade name.

A preferred example of chlorinated polymer is poly(vinyl chloride) or PVC. Such a polymer is in particular sold by Arkema under the Lacovyl® trade name. Other chlorinated polymers which can be used in this invention are chlorinated poly(vinyl chloride) (CPVC), such as the Lucalor® products from Arkema, and copolymers of vinyl chloride with monomers, such as acrylonitrile, ethylene, propylene or vinyl acetate, and also poly(vinylidene chloride) and its copolymers with vinyl monomers, in particular acrylic monomers. It is also possible for the chlorinated polymer used according to the invention to be a blend including at least two of the above chlorinated polymers or copolymers. In the case of vinyl chloride copolymers, it is preferable for the proportion of vinyl chloride units to be greater than 25% and preferably less than 99% of the total weight of the copolymer.

The halogenated polymers used according to the invention can be obtained according to suspension, microsuspension, emulsion or bulk polymerization processes well known to a person skilled in the art.

Advantageously, it is preferable to use poly(vinylidene fluoride) or PVDF.

The substrate made of halogenated polymer can, for example, have a thickness ranging from 5 to 500 μm, in particular from 20 to 100 μm and preferably from 25 to 60 μm. The halogenated polymer substrate can be surface-treated, for example by treatment of corona type, so as to improve its adhesion to the inorganic deposit layers. It is preferable generally to subject the substrate to any treatment which makes it possible to increase its surface tension to values of the order of 50-60 mN/m (or dyn/cm). The resistance of the substrate to radiation, in particular UV radiation, can be reinforced by addition of organic or inorganic UV stabilizers.

As indicated above, this polymer substrate is covered, on at least one of its faces, with at least one two-layer stack. This two-layer stack can be present on the face of the substrate turned toward the encapsulant and optionally on its opposite face. Each layer of this stack has a specific composition and a specific thickness. More specifically, this stack is composed of an SiO₂ layer and of a layer made of material of SiOₓN_{y}H_{z} type interposed between the substrate and the SiO₂ layer. The composition of the SiOₓN_{y}H_{z} layer is such that y and z are strictly greater than 0 and z is strictly less than the ratio (x+y)/5, advantageously z is strictly less than the ratio (x+y)/10. In addition, it is preferable for the value of x to decrease from the interface between the layer made of SiOₓN_{y}H_{z} and the SiO₂ layer toward the substrate and for the value of y to increase from the interface between the layer made of SiOₓN_{y}H_{z} and the SiO₂ layer toward the substrate. Preferably, x varies from 2 to 0 and/or y varies from a value strictly greater than 0 but less than 1 up to a value of 1. Furthermore, these layers exhibit thicknesses such that the thickness of the SiO₂ layer is less than or equal to 60 nm, the thickness of the layer made of SiOₓN_{y}H_{z} is greater than twice the thickness of the SiO₂ layer and the sum of the thicknesses of these layers is between 100 nm and 500 nm. Thus, the SiO₂ layer can, for example, have a thickness of 40 to 60 nm and the layer made of SiOₓN_{y}H_{z} can have a thickness ranging, for example, from 100 to 200 nm, in particular from 150 to 200 nm.

According to an advantageous embodiment of the invention, the Young's moduli M_{A} of the SiO₂ layer and M_{B} of the layer made of SiOₓN_{y}H_{z} are such that:
M_{A}>30 GPa, and
M_{B}<20 GPa.

These advantageous conditions with regard to the Young's moduli of the layers A and B make it possible to further improve the gas-barrier properties. The Young's moduli of the layers A and B can be measured according to the techniques described in the document “A simple guide to determine elastic properties of films on substrate from naoindentation experiments”, by S. Bec, A. Tonck and J. Loubet, in Philosophical Magazine, Vol. 86, Nos. 33-35, 21 Nov.-11 Dec. 2006, pp. 5347-5358, and in the document “In vivo measurements of the elastic mechanical properties of human skin by indentation tests”, in Medical Engineering & Physics, 30(2008), pp. 599-606. In addition, in this embodiment, the layer made of SiOₓN_{y}H_{z} is not only thicker than the SiO₂ layer but also less rigid than the latter, as a result of its lower Young's modulus, so that it makes it possible to better adjust the stresses and to limit the differential deformation between the SiO₂ layer and the substrate.

According to an advantageous embodiment of the invention, the refractive index of the multilayer structure is preferably greater than 1.5. The materials of its constituent layers can be amorphous.

The abovementioned two-layer stack can be formed according to a process which will now be described.

This process comprises a stage of conversion of a perhydropolysilazane (PHPS), that is to say of a compound of formula (I):

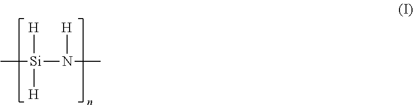

where n is an integer such that the number-average molecular weight of the PHPS is between 150 and 150 000 g/mol.

In this process, the PHPS is used in the form of a solution in a polar or nonpolar aprotic solvent, such as ethers (including dibutyl ether), esters, ketones, aliphatic or aromatic hydrocarbons (including xylene) or mixtures of these solvents. The concentration of the PHPS in the solution depends on the thickness of the liquid film to be deposited. For a film thickness of the order of 5 μm, it can thus range from 2% to 15% by weight of PHPS. The application of the PHPS solution to the substrate can be carried out by any known means, in particular by photogravure, flexography, coating by a slot die, centrifugation, roll coating, spraying or coating using Meyer rods. Furthermore, it is preferable for the deposition of PHPS to be carried out at ambient temperature.

In all the cases, the PHPS solution can be modified in order for the wettability of the solution during deposition to be suitable for the low surface free energy of certain halogenated substrates, such as PVDF, in particular when the latter is not surface-treated. Thus, in the case where the PHPS is used in the form of a solution in a polar aprotic solvent, such as dibutyl ether, it can be of use to dilute it using a nonpolar solvent, such as an alkane. The ratio by volume of the nonpolar solvent to the polar aprotic solvent can be adjusted by a person skilled in the art according to the chemical nature of the substrate and can in particular range from 1:10 to 1:2. In an alternative form, it is possible to increase the surface energy of the halogenated substrate by subjecting it to a plasma or corona treatment.

After application of the PHPS solution, the solvent is evaporated, either, on the one hand, by drying in the open air, under a stream of inert gas, such as nitrogen, or under vacuum, at ambient temperature, or, on the other hand, with an infrared lamp or hot air or hot depleted air or hot nitrogen. The PHPS layer deposited advantageously has a thickness, after the evaporation of the solvent, of between 100 and 400 nm, preferably between 150 and 350 nm, better still between 200 and 300 nm.

The conversion of the PHPS applied to the substrate can subsequently be carried out by means of irradiation using UV radiation at a wavelength of greater than or equal to 200 nm, in particular of between 240 and 280 nm, and, simultaneously or successively, by means of irradiation using vacuum ultraviolet radiation or VUV at a wavelength of less than or equal to 200 nm, in particular of between 180 and 200 nm, under an atmosphere exhibiting an oxygen content of less than 500 ppm and a water content of less than or equal to 1000 ppm.

The irradiation is generally carried out at ambient temperature and it can, for example, be carried out by means of a low pressure mercury lamp which combines a VUV wavelength of 185 nm and a UV wavelength of 254 nm. The dose received for the radiation at 185 nm is, for example, less than 20 joules/cm².

Very advantageously, the formation of the SiO₂ layer and the formation of the SiOₓN_{y}H_{z} layer are simultaneous. The process for the formation of these layers is carried out under specific conditions depleted in oxygen and in water which make it possible to limit the thickness of the SiO₂ layer and also the conversion of the layer made of SiOₓN_{y}H_{z} and thus to obtain the abovementioned characteristics of composition and of thickness of the layers.

In this embodiment, the duration of the irradiation depends on the thickness of the deposit and generally ranges from 1 to 10 minutes. For a thickness of 200 to 300 nm, an irradiation time of approximately 5 minutes is generally sufficient.

Alternatively, the process can take place in two stages: during a first stage, a PHPS layer is deposited on the substrate. This layer is subsequently subjected to UV irradiation with a wavelength of greater than 220 nm in the presence of a negligible oxygen and water content, i.e. less than 10 ppm. During a second stage, another PHPS layer is deposited on the first layer and then this second layer is subjected to irradiation by VUV at a wavelength of less than 200 nm in the presence of oxygen, the oxygen concentration then being between 10 ppm and 500 ppm.

It should be noted that the amount of remaining Si—H bonds after conversion of the PHPS in the SiO₂ and SiOₓN_{y}H_{z} layers is very low. It can be measured by Fourier transmission infrared spectrometry (FTIR), the spectra being recorded in attenuated total reflexion (ATR). This analysis makes it possible to monitor the kinetics of conversion of the PHPS, on the basis of the following table 1:

TABLE 1

| Wavenumber (cm⁻¹) | Bond characterized |
|---|---|
| 450-460, 800, 1070 | Si—O—Si |
| 800-900 | Si—N—Si |
| 880, 2100-2200 | H—Si—H |
| 940, 2800-3700 (broad band) | Si—OH |
| 1180 | Si—NH |
| 3350 | N—H |

According to another possibility, the low amount of Si—H can be detected in reflexion on the substrates described in the invention. The transmittance in the wavenumber range 2100-2300 cm⁻¹ is then greater than 80%, preferably greater than 90%.

In addition, the chemical composition of the layers after irradiation can be confirmed by time-of-flight secondary ionization mass spectrometry (TOF-SIMS), for example using an IontoF V spectrometer equipped with a source of Bi⁺ ions of 25 keV and 1.5 pA and with a source of Cs⁺ ions of 2 keV and 128 nA.

In addition to the substrate and the two-layer stack described above, the structure used according to the invention can comprise a layer of a polymer material deposited on the two-layer stack, for example by evaporation and/or polymerization. The polymer used in this layer may or may not be halogenated. It can in particular be chosen from hybrid materials, such as organosilanes, block polymer materials comprising a lamellar structure, which is cocontinuous or of matrix/inclusions type, such as acrylic block copolymers, for example poly(methyl methacrylate)-b-poly(butyl acrylate) or poly(methyl methacrylate)-b-poly(butyl acrylate)-b-poly(methyl methacrylate), or also composite or nanocomposite materials comprising a polymer matrix and reinforcements, such as carbon nanotubes, clays, zeolites, active charcoal and/or diatomaceous earths. The layer of polymer material preferably has a thickness of less than or equal to that of the substrate, even if layers of polymer material with a thickness greater than that of the substrate may be preferred in specific structures. The layers of this polymer material can have, independently of one another, a thickness of 1 to 30 μm, for example. It is thus possible to confer, on the multilayer structure used according to the invention, barrier properties toward other factors than gases, for example toward UV rays, or moisture absorption properties, for example. By virtue of the layer made of SiOₓN_{y}H_{z}, the problems of a mechanical nature during the deposition of the abovementioned layer made of polymer material are limited, such as the curvature of the combined structure.

In an alternative form or in addition, the multilayer structure can comprise n stacks, n being a positive integer greater than 1, each stack comprising an SiO₂ layer (A) and a layer (B) made of material of SiOₓᵢN_{yi}H_{zi} type, i being a positive integer of between 1 and n and zᵢ being strictly less than the ratio (xᵢ+yᵢ)/5, advantageously zᵢ is strictly less than the ratio (xᵢ+yᵢ)/10, xᵢ, yᵢ and zᵢ being identical or different for the various values of i. Such a structure can be prepared by repeating the stages of the process described above. The effect on the gas barrier properties is further enhanced.

A multilayer structure which is particularly preferred is that comprising one or more of the stacks described above, positioned symmetrically on both sides (front and back) of the substrate. Just one two-layer stack or n two-layer stacks can thus, advantageously, be positioned on the front side and back side of the polymer substrate.

The multilayer structures comprising n inorganic two-layer stacks (on one and/or other side of the substrate) can comprise at least one layer made of polymer material positioned between the SiO₂ layer of a stack and the layer made of SiOₓᵢN_{yi}H_{zi} of the stack directly following, for example n−1 layers made of polymer material, each of the layers made of polymer material being positioned between two stacks. The functional properties of the structure are thus enhanced as a result of the placing in series of n dense layers A, made of SiO₂ and of the n−1 interposition layers made of polymer material.

All the multilayer structures described above are of particular use as frontsheet of photovoltaic modules. It is preferable in this case for them to be transparent, that is to say for them to exhibit a total transmittance, measured according to the standard ASTM D1003, of greater than 85%. Furthermore, these structures can be inserted into opaque or transparent multilayer laminates which can act as backsheets of photovoltaic modules.

For these applications, the multilayer structure is formed beforehand according to conventional techniques for producing films, sheets or plaques. Mention may be made, by way of examples, of the techniques of blown film extrusion, extrusion-lamination, extrusion-coating, cast film extrusion or also extrusion of sheets. All these techniques are known to a person skilled in the art and he will know how to adjust the processing conditions of the various techniques (temperature of the extruders, connector, dies, rotational speed of the screws, cooling temperatures of the cooling rolls, and the like) in order to form the structure according to the invention having the desired shape and the desired thicknesses. It would not be departing from the invention if this structure were formed by pressing or rolling techniques with adhesives in the solvent or aqueous route or if it were subjected to an additional stage of annealing.

Another subject matter of the invention is thus a photovoltaic module including photovoltaic cells which are protected by an encapsulant, a protective frontsheet and a protective backsheet, in which the protective frontsheet and/or backsheet comprises a multilayer structure as described above and does not comprise a glass layer with a thickness of 50 μm or more.

As indicated above, the multilayer structure can constitute the protective frontsheet of the photovoltaic module. In this case, the protective backsheet can be composed of a three-layer structure including a central layer based on polyester, such as polyethylene terephthalate (PET), surrounded by two layers based on the fluorinated polymer, such as polyvinylidene fluoride (PVDF), polyvinyl fluoride (PVF) or poly(ethylene/tetrafluoroethylene) (ETFE). In an alternative form, the protective backsheet can be composed of polyolefins, in particular of polypropylene, optionally polyamide-grafted or functionalized by maleic anhydride, alone or in combination with one or more layers of optionally functionalized fluorinated polymer, such as PVDF. In a further alternative form, the protective backsheet can be composed of one or more polyamide layers optionally reinforced by glass fibers, used alone or in a multilayer structure comprising a central PET layer. In an alternative form or in addition, the protective backsheet can comprise a sheet of aluminum and/or glass.

In another embodiment of the invention, the multilayer structure described above is incorporated in the protective backsheet of a photovoltaic module. In this case, it can be combined with at least one of the constituent materials of the protective backsheets described above, thus improving in particular the barrier properties of the protective backsheet when the latter does not comprise a layer made of metal (such as aluminum) or glass. In addition, it can include various additives, including impact modifiers, inorganic or organic pigments, dyes, optical brighteners, coupling agents, crossing agents, plasticizers, heat stabilizers, stabilizers with regard to hydrolysis, antioxidants (for example of phenol and/or phosphite and/or amine type), reinforcements, such as glass fiber, flame retardants and their mixtures. The protective frontsheet can then be composed of glass, poly(methyl methacrylate) or PMMA, a fluorinated homo- or copolymer, such as PVDF, a blend of fluorinated polymer and PMMA, or multilayer structures obtained from these materials.

In all cases, the encapsulant is generally based on at least one polymer, such as an ethylene/vinyl acetate (EVA) copolymer, polyvinyl butyral (PVB), ionomers, poly(methyl methacrylate) (PMMA), a polyurethane, a polyester, a silicone elastomer and their blends.

In addition, the photovoltaic cells can comprise doped silicon, which is monocrystalline or polycrystalline, amorphous silicon, cadmium telluride, copper indium diselenide or organic materials, for example.

The photovoltaic module can be manufactured according to the processes known to a person skilled in the art and in particular as described in U.S. Pat. No. 5,593,532. In general, the assembling of the various layers can be carried out by hot or vacuum pressing, or hot rolling.

A better understanding of the invention will be obtained on reading the following nonlimiting examples, taken in combination with the appended figure, which illustrates the water vapor transmission rate of two different structures according to the invention, in comparison with a bare substrate.

### EXAMPLES

### Example 1

### Manufacture of a Multilayer Structure According to the Invention

A precursor solution was prepared by mixing a 20% commercial solution of PHPS (NN 120-20 (A), supplied by Clariant) in dibutyl ether with hexane as cosolvent, in a ratio by volume of hexane to dibutyl ether of 1:5. In order to limit the possible contamination of the surface of the substrate by particles capable of creating defects in the multilayer structure after conversion, the substrate was decontaminated using a Teknek sheet cleaning device before the deposition of the liquid precursor layer. The PHPS solution was subsequently applied to a substrate, composed of PVDF (Kynar® 740 from Arkema), with a thickness of 30 or 50 μm, as the case may be, and of A4 format, using a Meyer rod, so as to obtain a wet PHPS layer with a thickness of 4 to 6 μm. The solvent was then evaporated by drying in the open air at ambient temperature for a few minutes. The PHPS layer obtained had a thickness of 250 nm. The coated substrate was subsequently placed in a chamber under a continuous stream of dry nitrogen, so as to obtain a hygrometry of less than 1000 ppm and an oxygen content of between 10 and 500 ppm. The conversion of the PHPS by irradiation was then carried out using a low pressure mercury lamp, with VUV (185 nm) and UV (254 nm) radiation, for a period of time of 5 minutes, corresponding to a dose of the order of 10 J/cm².

A multilayer structure S1 in the film form was thus obtained.

### Example 2

### Evaluation of the Barrier Properties of the Structures According to the Invention

The rate of transmission of helium or water vapor in g·m⁻²·day⁻¹, also denoted by WVTR (Water Vapor Transmission Rate), as a function of the time in days was measured for different structures, namely:

I: a substrate made of PVDF polymer alone (Kynar® 740 from Arkema), having a thickness of 30 μm for the helium measurements and of 50 μm for the water vapor measurements
II: the structure S1 obtained in example 1
III: a structure S2 obtained in a similar manner to example 1, by deposition of two successive layers of PHPS, and thus including two stacks identical to that of the structure S1
IV: a comparative structure S1′ corresponding to the structure S1, except that the substrate was composed of PET
V: a structure S3 obtained in a similar manner to example 1, except that the PHPS layer was deposited on each side (front and back) of the substrate made of PVDF
VI: a comparative structure S3′ corresponding to the structure S3, except that the substrate was composed of PET.

In order to do this, a circular sample of each of these structures was cut out and then placed in an apparatus such as that described in the document US 2007/0186622.

The test protocol consists in placing the sample (substrate alone or coated) at the interface of a chamber comprising a controlled atmosphere and of a measurement chamber under high permanent vacuum (measurement of the flow by mass spectrometry). The temperatures of the substrate and of the atmosphere are kept constant (38° C.) while the hygrometry (in the case of water vapor) is saturated (liquid/vapor equilibrium). The precise value of the WVTR is obtained by virtue of the preliminary passage of a reference polymer of known WVTR (in the case in point, PET).

The structure S2 offers notable gas barrier properties, as is shown on the appended figure. It exhibits a WVTR (T=38° C., RH=100%) of 8×10⁻² g·m⁻²·day and a factor for improvement in the water barrier properties, with respect to the substrate alone, of 225, that is to say equivalent to that obtained with the best methods for the plasma deposition of inorganic layers.

Furthermore, the barrier properties of the structures tested, obtained in a helium permeation test, are collated in table 2 below.

The helium barrier properties are measured with the same apparatus as described above; in this case, the atmosphere saturated with water is replaced with an atmosphere of dry helium of known pressure. This is because it can be observed that the measurement of the helium permeability constitutes a reliable tool for evaluating the water barrier properties.

In this table, the barrier properties are expressed in terms of improvement factor, also denoted by BIF (Barrier Improvement Factor), with respect to the PVDF substrate alone.

TABLE 2
Barrier properties

| Sample | BIF He |
|---|---|
| PVDF substrate | 1 |
| S1 Structure | 7 |
| S2 Structure | 12 |
| S1′ Structure | 4 |
| S3 Structure | 25 |
| S3′ Structure | 8 |

As emerges from table 2, the addition of one (and more particularly of two) two-layer stack(s) makes it possible to significantly improve the barrier properties of the substrate based on halogenated polymer. The symmetrical structure comprising a two-layer stack on each side of the substrate (front and back) is particularly effective. In addition, the multilayer structures according to the invention exhibit helium barrier properties which are markedly superior to similar structures based on PET.

### Example 3

### Manufacture of Photovoltaic Modules and Evaluation of their Resistance to Aging

A photovoltaic mini-module was manufactured using the film of example 1, according to the following manufacturing procedure.

Two Suntech® photovoltaic cells with a side length of 125 mm were connected (vertical sequence of type 1×2, 1 column, 2 lines) by soldering copper conductive strips along the two busbars present in the starting cells. Such a sequence of cells is known as a 1×2 cell line.

The 1×2 cell line was placed between two sheets, cut to the A4 dimensions, of crosslinkable EVA-based encapsulant (VistaSolar® Fast Cure 486.00, supplied by Solutia), having a thickness of approximately 400 μm before lamination. The resulting assemblage was completed by a glass backsheet with a thickness of 3.2 mm, cut to the A4 dimensions, and also by the film of structure S1 obtained in example 1, which acted as frontsheet of the module. The uncoated face of the film of structure S1 was placed outside. This S1 frontsheet/crosslinkable EVA film/1×2 cell line/crosslinkable EVA film/glass assemblage was introduced, with the backsheet down below, into a semi-industrial laminator S1815/E from 3S, in order to carry out the manufacture of the module, according to the following lamination cycle.

The assemblage was introduced into the laminator, which was at a set temperature of 145° C. The laminator had two chambers separated by a flexible membrane. The module was in the bottom chamber in indirect contact with the heating plate of the laminator, owing to the fact that pins exiting from the heating plate supported the module, initially at a distance of the order of 1 cm from the plate. In a first phase of the lamination, the vacuum (down to less than 10 mbar) was produced in both chambers. This phase, referred to as degassing phase, lasted 5 minutes, during which the module began to rise in temperature. After 5 minutes, the lamination phase proper began and two events took place: 1) the pins were lowered and the module came into direct contact with the hot plate and 2) the pressure in the top chamber was brought to atmospheric pressure, while maintaining the bottom chamber under vacuum, so that the flexible membrane separating the two chambers became flattened against the module as a result of the difference in pressure (c. 1 bar) between the two chambers. This second phase lasted 10 minutes, after which the two chambers were brought back to atmospheric pressure and the module was removed from the laminator.

A photovoltaic module was thus obtained which is ready to be characterized.

This photovoltaic module was placed in an aging chamber at wet heat (85° C., 85% humidity) for 1000 hours and inspected after this time, in search of signs of aging or damage. The photovoltaic module exhibited very good behavior, without appearance of color (yellowing), and the adhesion between the layers was retained.

1. A photovoltaic module including photovoltaic cells protected by an encapsulant, a protective frontsheet and a protective backsheet, in which the protective frontsheet and/or backsheet comprises a multilayer structure characterized in that:
said multilayer structure comprises:
(a) a substrate including at least one halogenated polymer, and
(b) at least one stack of an SiO₂ layer (A) and of a layer (B) made of SiOₓN_{y}H_{z} positioned between the substrate and the layer (A), in which the layer (A) and the layer (B) exhibit thicknesses (t_{A},t_{B}) such that the thickness (t_{A}) of the layer (A) is less than or equal to 60 nm, the thickness (t_{B}) of the layer (B) is greater than twice the thickness (t_{A}) of the lam (A) and the sum of the thicknesses of the layer (A) and of the layer (B) is between 100 nm and 500 nm, and in which y and z are strictly greater than 0 and z is strictly less than the ratio (x+y)/5, advantageously z is strictly less than the ratio (x+y)/10,
said stack being positioned on the face of the substrate turned toward the encapsulant and optionally on the opposite face of the substrate;
and in that the protective frontsheet and/or backsheet in which the multilayer structure is included does not comprise a glass layer with a thickness of 50 μm or more.

2. The photovoltaic module as claimed in claim 1, characterized in that the value of x decreases from the interface between the layer (B) and the layer (A) toward the substrate and the value of y increases from the interface between the layer (B) and the layer (A) toward the substrate.

3. The photovoltaic module as claimed in claim 2, characterized in that x varies from 2 to 0 and/or y varies from a value strictly greater than 0 and less than 1 up to a value of 1.

4. The photovoltaic module as claimed in claim 1, characterized in that the material of the layer (A) exhibits a Young's modulus (M_{A}) of greater than or equal to 30 GPa and the material of the layer (B) has a Young's modulus (M_{B}) of less than or equal to 20 GPa.

5. The photovoltaic module as claimed in claim 1, characterized in that said at least one stack is obtained by conversion of a perhydropolysilazane, preferably by means of irradiation using UV radiation at a wavelength of greater than or equal to 200 nm and, simultaneously or successively, by means of irradiation using VUV radiation at a wavelength of less than or equal to 200 nm, under an atmosphere exhibiting an oxygen content of less than 500 ppm and a water content of less than or equal to 1000 ppm.

6. The photovoltaic module as claimed in claim 1, characterized in that the multilayer structure comprises a layer made of polymer material on the layer (A) of said stack, on the face opposite that in contact with the layer (B).

7. The photovoltaic module as claimed in claim 1, characterized in that the multilayer structure comprises n stacks, n being a positive integer greater than 1, each stack comprising an SiO₂ layer (A) and a layer (B) made of SiOₓᵢN_{yi}H_{zi}, i being a positive integer of between 1 and n and zᵢ being strictly less than the ratio (xᵢ+yᵢ)/5, advantageously z, is strictly less than the ratio (xᵢ+yᵢ)/10, xᵢ, yᵢ and zᵢ being identical or different for the various values of i.

8. The photovoltaic module as claimed in claim 7, characterized in that the multilayer structure comprises at least one layer made of polymer material positioned between the layer (A) of a stack and the layer (B) of the stack directly following.

9. The photovoltaic module as claimed in claim 8, characterized in that it comprises n−1 layers made of polymer material, each of the layers made of polymer material being positioned between two stacks.

10. The photovoltaic module as claimed in claim 1, characterized in that the multilayer structure comprises one or more stacks positioned symmetrically on both sides of the substrate.

11. The photovoltaic module as claimed in claim 1, characterized in that the halogenated polymer is chosen from chlorinated and/or fluorinated homo- and copolymers, preferably fluorinated homo- and copolymers.

12. The photovoltaic module as claimed in claim 11, characterized in that the fluorinated polymer is chosen from fluorinated homo- and copolymers comprising at least 50 mol % and advantageously composed of monomers of formula (I):
CFX═CHX′ (I)
where X and X′ independently denote a hydrogen or halogen (in particular fluorine or chlorine) atom or a perhalogenated (in particular perfluorinated) alkyl radical, such as:
poly(vinylidene fluoride) (PVDF), preferably in the α form,
copolymers of vinylidene fluoride with, for example, hexafluoropropylene (HFP), chlorotrifluoroethylene (CTFE), hexafluoropropylene (HFP), trifluoroethylene (VF3) or tetrafluoroethylene (TFE),
trifluoroethylene (VF3) homo- and copolymers,
fluoroethylene/propylene (FEP) copolymers,
copolymers of ethylene with fluoroethylene/propylene (FEP), tetrafluoroethylene (TFE), perfluoromethyl vinyl ether (PMVE), chlorotrifluoroethylene (CTFE) or hexafluoropropylene (HFP), and
their blends.

13. The photovoltaic module as claimed in claim 12, characterized in that the fluorinated homo- or copolymer is poly(vinylidene fluoride).

14. The photovoltaic module as claimed in claim 1, characterized in that the multilayer structure constitutes the protective frontsheet of the photovoltaic module.

15. (canceled)
